(19) United States
(12) Patent Application Publication
(10) Pub. No.: US 2026/0351891 A1
(43) Pub. Date: Nov. 5, 2026

(54) Power-Cooling Integrated Connector

(71) Applicant: AA Power Inc., Boston, MA (US)

(72) Inventor: Qun Lu, Lexington, MA (US)

(21) Appl. No.: 19/665,999

(22) Filed: May 1, 2026

Related U.S. Application Data
(60) Provisional application No. 63/798,901, filed on May 2, 2025.

(51) Int. Cl. H01R 13/516; H02G 5/10; H05K 7/20

(52) U.S. Cl. CPC H01R 13/516; H02G 5/10; H05K 7/20263; H05K 7/20418; H05K 7/205

(57) ABSTRACT

A system may include a power supply unit, and a connector configured to accommodate an electrical connector portion of the power supply unit. The connector comprises a connector body, a metal heat sink, and a liquid cooling system. The connector body comprises a plurality of power contacts and an insulating housing. The plurality of power contacts is configured to receive the electrical connector portion of the power supply unit. The insulating housing is configured to provide electrical isolation. The metal heat sink partially encloses the insulating housing and is configured to dissipate heat. The liquid cooling system comprises a channel through which coolant flows to dissipate heat generated at the electrical connector portion of the power supply unit.

### PRIORITY

This application claims the benefit of U.S. Provisional Application No. 63/798,901, filed on May 2, 2025, entitled “Power-cooling Integrated Connector,” which application is hereby incorporated herein by reference.

### TECHNICAL FIELD

The present disclosure relates generally to the field of power conversion systems, and in particular to a power-cooling integrated connector for high power applications.

### BACKGROUND

As technologies further advance, a modern data center is equipped with numerous high-performance processors such as graphics processing units (GPUs). The processors are designed to handle intensive computing workloads such as artificial intelligence (AI) training, machine learning, and complex simulations. These GPUs, often organized into high-density racks, deliver exceptional parallel processing power, enabling the rapid analysis and processing of vast amounts of data.

To support these high-performance computing tasks, power supply units (PSUs) play a vital role in delivering stable and regulated electrical power to various subsystems. In data centers and other high-demand environments, PSUs often operate under high current and sustained load conditions, which can generate substantial heat. Effective thermal management is essential to maintaining system reliability and preventing component failure due to overheating.

At the interface between PSUs and downstream components, power connectors serve as the critical link for conducting electrical current from the supply to the load. Traditional power connectors used in AI server systems and similar applications primarily rely on air convection for cooling. As power demands rise, these connectors struggle with insufficient cooling efficiency under high loads or prolonged operation, resulting in overheating. Overheating in air-cooled connectors can cause insulation materials to melt or burn, leading to potential issues such as electrical arcing, sparks, or even fire hazards. Additionally, the limited current-carrying capacity of these air-cooled connectors hinders their ability to meet the increasing power requirements of AI computing systems, posing a critical bottleneck in power supply design.

It is thus desirable to develop improved power connector designs capable of operating reliably under high-current conditions. The present invention proposes a power-cooling integrated connector that achieves efficient heat dissipation by directly coupling a liquid cooling system with a power interface.

### SUMMARY

Technical advantages are generally achieved, by embodiments of this disclosure which describe a power-cooling integrated connector for high power applications.

In accordance with one aspect of the present disclosure, a power conversion system is provided that includes: a power supply unit; and a connector configured to accommodate an electrical connector portion of the power supply unit, the connector comprising: a connector body comprising a plurality of power contacts and an insulating housing, wherein the plurality of power contacts are configured to receive the electrical connector portion of the power supply unit, and the insulating housing is configured to provide electrical isolation; a metal heat sink partially enclosing the insulating housing and configured to dissipate heat; and a liquid cooling system comprising a channel through which coolant flows to dissipate heat generated at the electrical connector portion of the power supply unit.

The foregoing has outlined rather broadly the features and technical advantages of the present disclosure in order that the detailed description of the disclosure that follows may be better understood. Additional features and advantages of the disclosure will be described hereinafter which form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

For a more complete understanding of the present disclosure, and the advantages thereof, reference is now made to the following descriptions taken in conjunction with the accompanying drawings, in which:

FIG. 1A is an overall appearance view of an example power-cooling integrated connector in accordance with various embodiments of the present disclosure;

FIG. 1B is a perspective side view of a connector body of the example power-cooling integrated connector in accordance with various embodiments of the present disclosure;

FIG. 1C is a perspective side view of a metal heat sink of the example power-cooling integrated connector in accordance with various embodiments of the present disclosure;

FIG. 2A is an overall appearance view of an example power-cooling integrated connector in accordance with various embodiments of the present disclosure;

FIG. 2B is a perspective top view of a metal heat sink of the example power-cooling integrated connector in accordance with various embodiments of the present disclosure;

FIG. 2C is a perspective side view of the metal heat sink of the example power-cooling integrated connector in accordance with various embodiments of the present disclosure;

FIG. 3A is an overall appearance view of an example power-cooling integrated connector in accordance with various embodiments of the present disclosure;

FIG. 3B is a perspective side view of a finned metal heat sink of the example power-cooling integrated connector in accordance with various embodiments of the present disclosure;

FIG. 3C is a perspective front view of the finned metal heat sink of the example power-cooling integrated connector in accordance with various embodiments of the present disclosure;

FIG. 4A illustrates an overall appearance view of an example power-cooling integrated connector in accordance with various embodiments of the present disclosure;

FIG. 4B illustrates a perspective view of a metal heat sink of the example power-cooling integrated connector in accordance with various embodiments of the present disclosure;

FIG. 4C illustrates a perspective top view of the example power-cooling integrated connector in accordance with various embodiments of the present disclosure;

FIG. 4D illustrates a perspective side view of the example power-cooling integrated connector in accordance with various embodiments of the present disclosure;

FIG. 4E illustrates a perspective front view of the example power-cooling integrated connector in accordance with various embodiments of the present disclosure;

FIG. 4F illustrates a cross-sectional view of the example power-cooling integrated connector along line A–A’ in accordance with various embodiments of the present disclosure;

FIG. 5A illustrates an overall appearance view of an example power-cooling integrated connector in accordance with various embodiments of the present disclosure; and

FIG. 5B illustrates a cross-sectional view of the example power-cooling integrated connector in accordance with various embodiments of the present disclosure.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of embodiments of this disclosure are discussed in detail below. It should be appreciated, however, that the concepts disclosed herein can be embodied in a wide variety of specific contexts, and that the specific embodiments discussed herein are merely illustrative and do not serve to limit the scope of the claims. Further, it should be understood that various changes, substitutions and alterations can be made herein without departing from the spirit and scope of this disclosure as defined by the appended claims.

Further, one or more features from one or more of the following described embodiments may be combined to create alternative embodiments not explicitly described, and features suitable for such combinations are understood within the scope of this disclosure. It is therefore intended that the appended claims encompass any such modifications or embodiments.

The present disclosure will be described with respect to preferred embodiments in a specific context, namely a power-cooling integrated connector that achieves efficient heat dissipation by coupling to or integrated with a liquid cooling system with a power interface. The power-cooling integrated connector is configured to accommodate an electrical connector portion of the power supply unit (PSU). Hereinafter, various embodiments will be explained in detail with reference to the accompanying drawings.

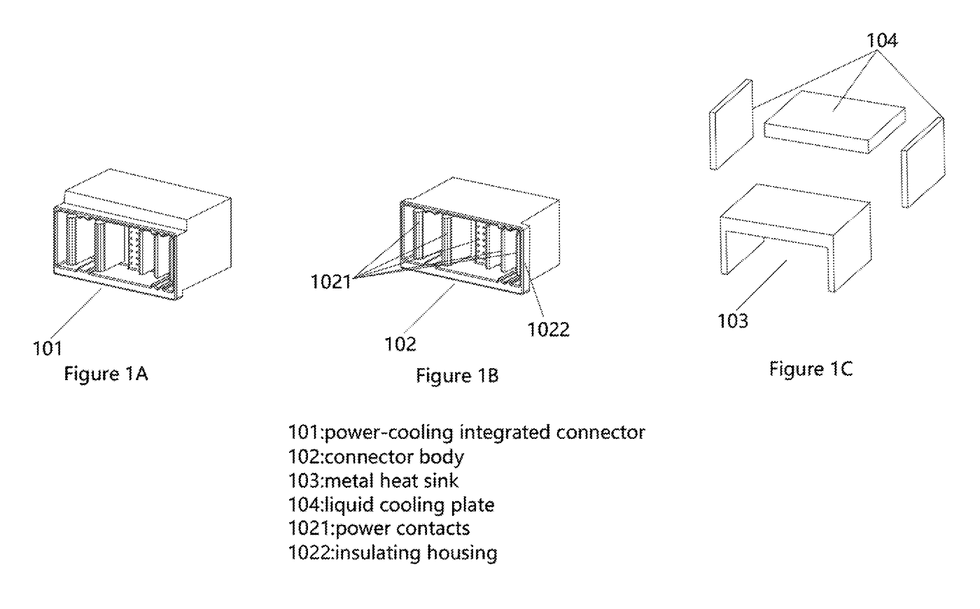

FIGS. 1A-1C illustrate an example of a power-cooling integrated connector 101 in accordance with various embodiments of the present disclosure. FIG. 1A is an overall appearance view of the power-cooling integrated connector 101. The power-cooling integrated connector 101 comprises a connector body 102, a metal heat sink 103, and a liquid cooling plate 104.

FIG. 1B is a perspective side view of the connector body 102 of the power-cooling integrated connector 101. As illustrated in FIG. 1B, the connector body 102 comprises power contacts 1021 and an insulating housing 1022. The power contacts 1021 are configured to receive the electrical connector portion of the power supply unit. The power contacts 1021 are formed from a high-conductivity metal, such as copper alloy, to support high current transmission. The insulating housing 1022 is configured to provide electrical isolation. The insulating housing 1022 may be composed of engineering plastics or ceramic to provide electrical isolation.

FIG. 1C is a perspective side view of the metal heat sink 103 of the power-cooling integrated connector 101. The metal heat sink 103, as illustrated in FIG. 1C, is U-shaped and is configured to partially enclose the insulating housing 1022 of the connector body 102. The metal heat sink 103 is shaped to fit over the top and both sides of the connector body 102, thereby forming a three-sided enclosure, while leaving the front and rear faces of the connector body 102 exposed. The metal heat sink 103 comprises a top portion and a pair of opposing sidewalls connected to the top portion. The metal heat sink 103 is made of high thermal conductivity metal such as aluminum or copper. The metal heat sink 103 is configured to dissipate heat.

The power-cooling integrated connector 101 may further comprise a thermally conductive insulating medium. The thermally conductive insulating medium meets both electrical isolation and heat conduction requirements. The inner side of the metal heat sink is bonded to the outer surface of the insulating housing via the thermally conductive insulating media (e.g., thermal silicone pads, ceramic plates).

The liquid cooling plate 104 is positioned on both sidewalls and the top portion of the metal heat sink 103 and is fixed to the outer side of the metal heat sink 103 through planar contact or welding. The liquid cooling plate 104 is thermally coupled to the outer surface of the heat sink 103. The liquid cooling plate 104 features an internal serpentine channel through which coolant flows to dissipate heat generated at the electrical connector portion of the power supply unit. The internal serpentine channel is connected to external coolant circulation pipelines.

During operation, electrical current flowing through the power-cooling integrated connector 101 generates heat. The heat is first transmitted to the thermally conductive insulating medium, which maintains electrical isolation while enabling thermal transfer. The heat is then transmitted to the U-shaped metal heat sink 103 that partially encloses the connector body 102, facilitating heat dissipation. The heat is then transferred to the liquid cooling plate 104 secured to the outer surface of the metal heat sink 103. As coolant circulates through the internal serpentine channel of the liquid cooling plate 104, it absorbs and removes the heat, thereby achieving effective thermal management of the connector under high-current conditions. The U-shaped configuration of the metal heat sink increases the contact area for heat dissipation while enabling rapid heat equalization via the liquid cooling plate 104.

In some embodiments, the thermally conductive insulating medium may be omitted. For example, if the connector housing is made of a material that provides both electrical insulation and sufficient thermal conductivity, direct thermal contact between the connector housing 1022 and the metal heat sink 103 may be employed.

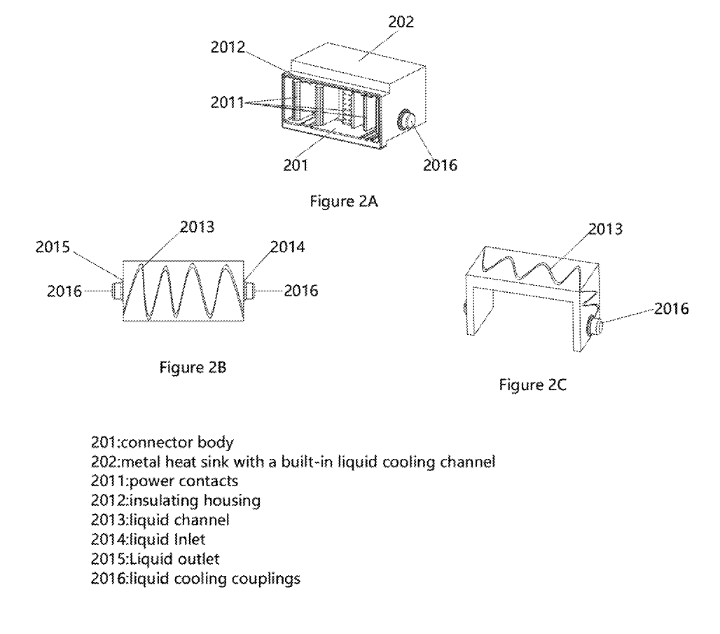

FIGS. 2A-2C illustrate another example of a power-cooling integrated connector in accordance with various embodiments of the present disclosure. As illustrated in FIGS. 2A-2C, the power-cooling integrated connector comprises a connector body 201 and a metal heat sink 202 with a built-in liquid cooling channel. FIG. 2A is an overall appearance view of the power-cooling integrated connector. The connector body 201 comprises power contacts 2011 and an insulating housing 2012. The power contacts 2011 are configured to receive the electrical connector portion of the power supply unit. The power contacts 2011 are formed from a high-conductivity metal, such as copper alloy, to support high current transmission. The insulating housing 2012 is configured to provide electrical isolation. The insulating housing may be composed of engineering plastics or ceramic to provide electrical isolation.

FIG. 2B is a perspective top view of the metal heat sink 202, illustrating the integrated liquid cooling channel 2013. FIG. 2C is a perspective side view of the metal heat sink 202, illustrating the integrated liquid cooling channel. The metal heat sink 202, as illustrated in FIG. 2C, is U-shaped and is configured to partially enclose the insulating housing of the connector body 201. The metal heat sink 202 is shaped to fit over the top and both sides of the connector body 201, thereby forming a three-sided enclosure, while leaving the front and rear faces of the connector body 201 exposed. The metal heat sink 202 comprises a top portion and a pair of opposing sidewalls connected to the top portion. The metal heat sink 202 is made of high thermal conductivity metal such as aluminum or copper.

The power-cooling integrated connector may further comprise a thermally conductive insulating medium. The thermally conductive insulating medium meets both electrical isolation and heat conduction requirements. The inner surface of the metal heat sink is bonded to the outer surface of the insulating housing via the thermally conductive insulating media (e.g., thermal silicone pads, ceramic plates).

As illustrated in FIGS. 2B and 2C, the metal heat sink 202 comprises a built-in liquid cooling channel 2013, which is located on both sidewalls and the top portion of the metal heat sink 202. In some embodiments, the liquid cooling channel 2013 has a serpentine configuration to increase the surface area for heat exchange. The liquid cooling channel 2013 comprises a liquid inlet 2014 and a liquid outlet 2015, and is configured to connect with an external liquid cooling system or coolant circulation pipelines. Coolant from the external liquid cooling system or the external circulation pipelines enters the liquid cooling channel 2013 through the liquid inlet 2014 and exits through the liquid outlet 2015.

In some embodiments, the power-cooling integrated connector may further comprise two liquid cooling couplings 2016, as illustrated in FIGS. 2A-2C. The liquid cooling couplings 2016 are mounted at the liquid inlet 2014 and liquid outlet 2015 ports and enable quick connection and disconnection of coolant hoses to the corresponding liquid inlets and outlets. The quick-connect liquid cooling couplings 2016 facilitate installation and maintenance, supporting modular equipment design. The equipment-side liquid cooling plate is connected to the liquid cooling couplings 2016 via flexible tubing, forming a closed coolant circulation loop.

During operation, electrical current flowing through the power-cooling integrated connector generates heat. The heat is first transmitted to the thermally conductive insulating medium, which maintains electrical isolation while enabling thermal transfer. The heat is then transmitted to the U-shaped metal heat sink 202 that partially encloses the connector body 201, facilitating heat dissipation. The heat is subsequently transferred to the integrated liquid cooling channel 2013. As coolant circulates through the internal liquid cooling channel 2013, it absorbs and removes the heat, thereby achieving effective thermal management of the connector under high-current operating conditions. The U-shaped configuration of the metal heat sink 202 increases the contact area for thermal conduction and promotes rapid heat equalization in conjunction with the integrated liquid cooling channel 2013. The built-in liquid cooling channel 2013 is directly integrated into the metal heat sink 202, thereby reducing thermal resistance layers and improving heat transfer efficiency.

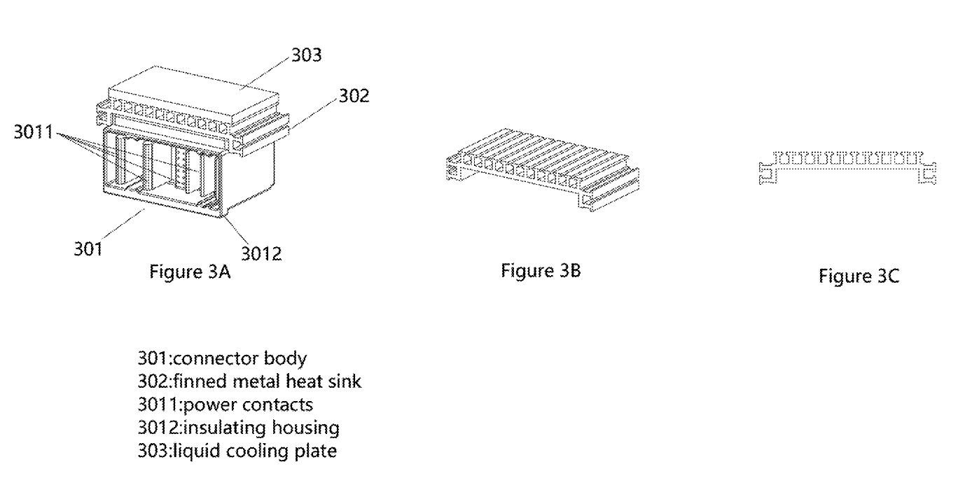

FIGS. 3A-3C illustrate another example of a power-cooling integrated connector in accordance with various embodiments of the present disclosure. The power-cooling integrated connector comprises a connector body 301, and a finned metal heat sink 302 coupled with liquid cooling plate 303. FIG. 3A is an overall appearance view of the power-cooling integrated connector. The connector body 301 includes power contacts 3011 and an insulating housing 3012. The power contacts 3011 are configured to receive the electrical connector portion of the power supply unit. The power contacts 3011 are formed from a high-conductivity metal, such as copper alloy, to support high current transmission. The insulating housing 3012 is configured to provide electrical isolation. The insulating housing 3012 may be composed of engineering plastics or ceramic to provide electrical isolation.

The power-cooling integrated connector may further comprise a thermally conductive insulating medium. The thermally conductive insulating medium meets both electrical isolation and heat conduction requirements. The inner surface of the finned metal heat sink is bonded to the outer surface of the insulating housing via the thermally conductive insulating media (e.g., thermal silicone pads, ceramic plates).

FIG. 3B is a perspective side view of the finned metal heat sink 302. FIG. 3C is a perspective front view of the finned metal heat sink 302. The metal heat sink 302 comprises a plurality of parallel fins on its top surface and sidewalls, which increase the surface area available for heat dissipation. The finned metal heat sink 302 is U-shaped and is configured to partially enclose the insulating housing 3012 of the connector body 301. The finned metal heat sink 302 is shaped to fit over the top and both sides of the connector body 301, thereby forming a three-sided enclosure, while leaving the front and rear faces of the connector body 301 exposed. In some embodiments, the finned metal heat sink only covers partially the sidewalls of the connector body 301. The finned metal heat sink 302 is made of high thermal conductivity metal such as aluminum or copper. The finned structure is coupled with the liquid cooling plate 303.

The power-cooling integrated connector further comprises a liquid cooling plate 303, which is positioned on all four sides of the equipment. The liquid cooling plate 303 is fixed to outer three sides of the U-shaped heat sink 302 via (concave-convex) contact. In some embodiments, the liquid cooling plate 303 comprises an internal serpentine channel through which coolant flows to dissipate heat generated at the electrical connector portion of the power supply unit. The internal serpentine channel comprises a liquid inlet and a liquid outlet, and is configured to connect with an external liquid cooling system or coolant circulation pipelines. Coolant from the external liquid cooling system or the external circulation pipelines enters the internal serpentine channel through the liquid inlet and exits through the liquid outlet.

During operation, electrical current flowing through the power-cooling integrated connector generates heat. The heat is first transmitted to the thermally conductive insulating medium, which maintains electrical isolation while enabling thermal transfer. The heat is then transmitted to the finned metal heat sink 302 that partially encloses the connector body 301, facilitating heat dissipation. The heat is subsequently transferred to the internal serpentine channel of the liquid cooling plate 303. As coolant circulates through the internal serpentine channel, it absorbs and removes the heat, thereby achieving effective thermal management of the connector under high-current operating conditions. The U-shaped configuration of the finned metal heat sink 302 increases the contact area for thermal conduction and promotes rapid heat equalization in conjunction with the liquid cooling channel.

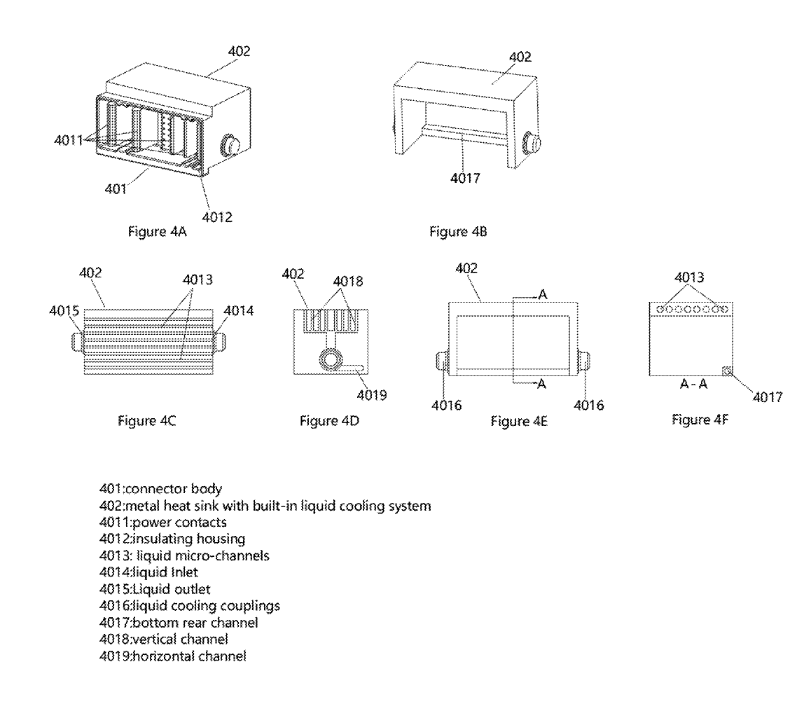

FIGS. 4A-4F illustrate another example of a power-cooling integrated connector in accordance with various embodiments of the present disclosure. As illustrated in FIGS. 4A-4F, the power-cooling integrated connector comprises a connector body 401, and a metal heat sink 402 with built-in liquid cooling system.

FIG. 4A illustrates an overall appearance view of the power-cooling integrated connector. The connector body 401 includes power contacts 4011 and an insulating housing 4012. The power contacts 4011 are formed from a high-conductivity metal, such as copper alloy, to support high current transmission. The power contacts 4011 are configured to receive the electrical connector portion of the power supply unit. The insulating housing 4012 may be composed of engineering plastics or ceramic to provide electrical isolation.

The power-cooling integrated connector may further comprise a thermally conductive insulating medium. The thermally conductive insulating medium meets both electrical isolation and heat conduction requirements. The inner surface of the metal heat sink is bonded to the outer surface of the insulating housing via the thermally conductive insulating media (e.g., thermal silicone pads, ceramic plates).

FIG. 4B illustrates a perspective view of the metal heat sink 402. The metal heat sink 402 is U-shaped and configured to partially enclose the insulating housing 4012 of the connector body 401. The metal heat sink 402 is shaped to fit over the top and both sides of the connector body 401, thereby forming a three-sided enclosure, while leaving the front and rear faces of the connector body 401 exposed. The metal heat sink 402 is made of a high thermal conductivity metal such as aluminum or copper. The metal heat sink comprises a top portion and a pair of opposing sidewalls connected to the top portion.

In some embodiments, the power-cooling integrated connector may comprise two liquid cooling couplings 4016 located on opposite sidewalls, such as the left and right sidewalls of the metal heat sink 402. The liquid cooling couplings 4016 are mounted at the inlet 4014 and outlet 4015 ports and enable quick connection and disconnection of external coolant hoses to the corresponding liquid inlets and outlets. The quick-connect liquid cooling couplings 4016 facilitate installation and maintenance, supporting modular equipment design. The equipment-side liquid cooling plate is connected to the liquid cooling couplings 4016 via flexible tubing, forming a closed coolant circulation loop.

As illustrated in FIG. 4B, the built-in liquid cooling system integrated to the metal heat sink 402 may comprise a bottom rear channel 4017 positioned near to the lower rear portion of the metal heat sink 402. The bottom rear channel 4017 extends from the left sidewall to the right sidewall of the metal heat sink 402.

FIG. 4C illustrates a perspective top view of the example power-cooling integrated connector, illustrating the built-in liquid cooling system. FIG. 4D illustrates a perspective side view of the example power-cooling integrated connector, illustrating the built-in liquid cooling system. As illustrated in FIGS. 4C and 4D, the built-in liquid cooling system integrated to the metal heat sink 402 may further comprise a plurality of liquid micro-channels 4013, which are formed in the top portion and the sidewalls of the metal heat sink 402. The plurality of liquid micro-channels 4013 are arranged in parallel to one another. In some embodiments, the plurality of liquid micro-channels 4013 are evenly spaced from one another. From a top view of the metal heat sink 402, the left ends of the plurality of liquid micro-channels 4013 align with the left end of the metal heat sink 402, and the right ends of the plurality of liquid micro-channels 4013 align with the right end of the metal heat sink 402.

As illustrated in FIG. 4D, the built-in liquid cooling system integrated to the metal heat sink 402 may further comprise a vertical channel 4018 and a horizontal channel 4019 on its sidewalls. The plurality of liquid micro-channels 4013 extend from the top portion of the metal heat sink 402 down along both sidewalls of the metal heat sink, and are fluidly connected to the vertical channel 4018. The vertical channel 4018 is further connected to the liquid cooling couplings 4016. The horizontal channel 4019 is fluidly connected to the bottom rear channel 4017, which is located at the lower rear portion of the metal heat sink 402. The horizontal channel 4019 is further connected to the liquid cooling couplings 4016. The bottom rear channel 4017 is fluidly connected to the plurality of liquid micro-channels 4013.

FIG. 4E illustrates a perspective front view of the example power-cooling integrated connector, illustrating the liquid cooling couplings 4016. As illustrated in FIG. 4E, the liquid cooling couplings 4016 are located on the opposite sidewalls of the metal heat sink 402.

FIG. 4F illustrates a cross-sectional view of the example power-cooling integrated connector along line A–A’, illustrating the built-in liquid cooling system. As illustrated in FIG. 4F, the plurality of liquid micro-channels 4013 in the top portion of the metal heat sink 402 are beneath the top surface of the metal heat sink 402. In some embodiments, the liquid micro-channels 4013 are cylindrical in shape, as shown in the cross-sectional view. The bottom rear channel 4017 is located near the lower rear portion of the metal heat sink 402. In some embodiments, the bottom rear channel 4017 is located at the bottommost corner of the metal heat sink 402. The bottom rear channel 4017 may be cylindrical or rectangular in shape. The bottom rear channel 4017 may also be located at the other portion of the heat sink 402 depending on system design.

During operation, electrical current flowing through the power-cooling integrated connector generates heat. The heat is first transmitted to the thermally conductive insulating medium, which maintains electrical isolation while enabling thermal transfer. The heat is then transmitted to the U-shaped metal heat sink 402 that partially encloses the connector body 401, facilitating heat dissipation. The heat is subsequently transferred to the integrated cooling system, including the built-in liquid micro-channels 4013 and the bottom rear channel 4017. As coolant circulates through the integrated cooling system, it absorbs and removes the heat, thereby achieving effective thermal management of the connector under high-current operating conditions. The U-shaped configuration of the metal heat sink 402 increases the contact area for thermal conduction and promotes rapid heat equalization in conjunction with the integrated liquid cooling system.

The power-cooling integrated connector described in FIGS. 4A-4F offers several key advantages, including improved cooling efficiency, space optimization, and enhanced reliability. Experimental results demonstrate a 40%–60% reduction in connector temperature rise under the same load conditions. The integrated heat dissipation structure saves internal equipment space. In addition, the liquid cooling system ensures stable temperature control and significantly extend the lifespan of the connectors.

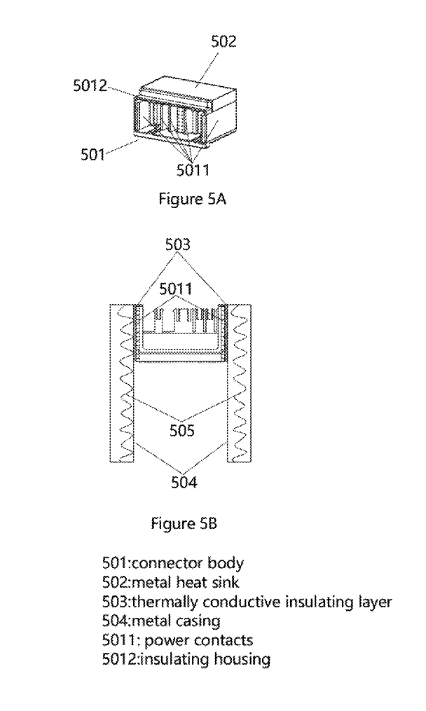

FIGS. 5A and 5B illustrate another example of a power-cooling integrated connector in accordance with various embodiments of the present disclosure. As illustrated in FIGS. 5A and 5B, the power-cooling integrated connector comprises a connector body 501, a metal heat sink 502, a thermally conductive insulating layer 503, and a metal casing 504.

FIG. 5A illustrates an overall appearance view of the power-cooling integrated connector in accordance with various embodiments of the present disclosure. The connector body 501 includes power contacts 5011 and an insulating housing 5012. The power contacts 5011 are formed from a high-conductivity metal, such as copper alloy, to support high current transmission. The power contacts 5011 are configured to receive the electrical connector portion of the power supply unit. The insulating housing 5012 may be composed of engineering plastics or ceramic to provide electrical isolation.

The metal heat sink 502 is U-shaped and configured to partially enclose the insulating housing 5012 of the connector body 501. The metal heat sink 502 is shaped to fit over the top and both sides of the connector body 501, thereby forming a three-sided enclosure, while leaving the front and rear faces of the connector body 501 exposed. The metal heat sink 502 is made of a high thermal conductivity metal such as aluminum or copper. The metal heat sink 502 comprises a top portion and a pair of opposing sidewalls connected to the top portion.

FIG. 5B illustrates a cross-sectional view of the power-cooling integrated connector, taken along a horizontal plane that intersects the power-cooling integrated connector. In this view, the metal casing 504 is rectangular in shape and is curved to wrap around the outer surfaces of the metal heat sink 502. The outer sidewalls of the metal heat sink 502 are in contact with the metal casing 504, as illustrated in FIGS. 5A and 5B. At least a portion of the metal casing 504 is bent inward toward the power contacts 5011, such that the power contacts 5011 are positioned adjacent to the portion of the metal casing 504. The thermally conductive insulating layer 503 is sandwiched between the portion of the metal casing 504 and the power contacts 5011, allowing for effective heat transfer while maintaining electrical isolation. The thermally conductive insulating layer 503 may be formed from insulating materials such as thermal silicone pads or ceramic plates.

According to one embodiment of the present disclosure, the U-shaped metal heat sink 502 is integrated with an internal liquid cooling channel. In some embodiments, the internal liquid cooling channel has a serpentine configuration to increase the surface area for heat exchange and enhance cooling efficiency. Thus, heat transferred through the metal casing 504 is dissipated via the liquid cooling channel of the metal heat sink 502. The side of the connector having the exposed power contacts 5011 or pins is positioned adjacent to the liquid cooling channel of the metal heat sink 502, allowing for heat dissipation.

During operation, electrical current flowing through the power-cooling integrated connector generates heat. This heat is first transferred to the thermally conductive insulating layer 503, which maintains electrical isolation while enabling thermal conduction. The heat is then transmitted to the metal casing 504, which collects and directs it to the metal heat sink 502. As coolant circulates through the internal liquid cooling channel of the metal heat sink 502, it absorbs and removes the heat, thereby achieving effective thermal management of the connector under high-current operating conditions.

In an alternative embodiment, the metal casing positioned on both sides of the connector may comprise an internal liquid cooling channel 505 configured to circulate coolant and dissipate heat away from the power contact region. In some embodiments, the internal liquid cooling channel 505 has a serpentine configuration to increase the surface area for heat exchange and enhance cooling efficiency. Furthermore, the metal case can be part of the conductive components of the power supply, such as a busbar, which can be directly attached to the power contacts of the connector while providing current-carrying and heat dissipation.

During operation, electrical current flowing through the power-cooling integrated connector generates heat. The heat is first transmitted to the thermally conductive insulating layer 503, which maintains electrical isolation while enabling thermal transfer. The heat is then transmitted to the U-shaped metal heat sink 502 and the metal casing 504 integrated with internal liquid cooling channel 505. As coolant circulates through the metal casing 504, it absorbs and removes the heat, thereby achieving effective thermal management of the connector under high-current operating conditions.

The core innovations of the power-cooling integrated connector described in various embodiments of the present disclosure include a structurally integrated design in which the metal housing or heat sink is integrally designed with liquid cooling channels, effectively shortening the heat conduction path and enhancing heat dissipation efficiency. Active heat dissipation through liquid circulation enables dynamic cooling, making the connector adaptable for high-power fluctuation scenarios. Additionally, the design maintains a compact form factor and is compatible with existing liquid cooling systems of equipment without increasing connector’s size.

Features described in the context of one embodiment may be used in combination with other embodiments. For example, each of the optional features described above in the context of the apparatus may be used in combination with the system. Each of the optional features described above in the context of the method may be used in combination with the system. Each of the optional features described above in the context of the apparatus may be used in combination with the method.

Although the description has been described in detail, it should be understood that various changes, substitutions and alterations can be made without departing from the spirit and scope of this disclosure as defined by the appended claims. Moreover, the scope of the disclosure is not intended to be limited to the particular embodiments described herein, as one of ordinary skill in the art will readily appreciate from this disclosure that processes, machines, manufacture, compositions of matter, means, methods, or steps, presently existing or later to be developed, may perform substantially the same function or achieve substantially the same result as the corresponding embodiments described herein. Accordingly, the appended claims are intended to include within their scope such processes, machines, manufacture, compositions of matter, means, methods, or steps.

What is claimed:

1. A system comprising:
a power supply unit; and
a connector configured to accommodate an electrical connector portion of the power supply unit, the connector comprising:
a connector body comprising a plurality of power contacts and an insulating housing, wherein the plurality of power contacts is configured to receive the electrical connector portion of the power supply unit, and the insulating housing is configured to provide electrical isolation;
a metal heat sink partially enclosing the insulating housing and configured to dissipate heat;
a metal casing configured to dissipate heat; and
a liquid cooling system comprising a channel through which coolant flows to dissipate heat generated at the electrical connector portion of the power supply unit.

2. The system of claim 1, wherein the metal heat sink is U-shaped and comprises a top portion and a pair of opposing side walls connected to the top portion.

3. The system of claim 2, further comprising:
a thermally conductive insulating medium, wherein an inner surface of the metal heat sink is bonded to an outer surface of the insulating housing via the thermally conductive insulating medium, the thermally conductive insulating medium being configured to provide electrical isolation and heat conduction.

4. The system of claim 3, wherein the plurality of power contacts is formed from a high-conductivity metal.

5. The system of claim 3, wherein the liquid cooling system is externally secured to the sidewalls and top portion of the metal heat sink through planar contact or welding.

6. The system of claim 3, wherein the liquid cooling system is integrated into the metal heat sink, with the channel of the liquid cooling system located in the sidewalls and top portion of the metal heat sink, wherein coolant from external liquid circulation pipelines enters the channel of the liquid cooling system through a liquid inlet and exits through a liquid outlet.

7. The system of claim 6, wherein the channel of the liquid cooling system is serpentine in shape.

8. The system of claim 3, wherein the liquid cooling system is integrated into the metal heat sink, and the liquid cooling system further comprises a plurality of liquid micro-channels formed in the sidewalls and top portion of the metal heat sink, the plurality of liquid micro-channels being arranged in parallel and evenly spaced from one another.

9. The system of claim 8, wherein the channel of the liquid cooling system is positioned at a lower rear portion of the metal heat sink and is fluidly connected to the plurality of liquid micro-channels.

10. The system of claim 3, wherein the metal heat sink comprises a finned structure formed on the top portion and sidewalls of the metal heat sink, the finned structure being coupled with the liquid cooling system.

11. The system of claim 10, wherein the liquid cooling system is secured to the sidewalls and top portion of the metal heat sink via concave-convex surface contact, the liquid cooling system comprising an internal serpentine channel connected to external coolant circulation pipelines.

12. The system of claim 3, wherein the connector further comprises a pair of quick-connect liquid cooling couplings located on the opposing sidewalls of the metal heat sink, wherein coolant from external coolant circulation pipelines flows into the channel of the liquid cooling system by connecting the external coolant circulation pipelines to the liquid cooling couplings.

13. The system of claim 2, wherein:
a first portion of the metal casing is positioned adjacent to the plurality of power contacts;
a second portion of the metal casing is in contact with an outer surface of the sidewalls of the metal heat sink; and
a thermally conductive insulating layer is positioned between the first portion of the metal casing and the plurality of power contacts.

14. The system of claim 13, wherein the channel of the liquid cooling system is located in the metal heat sink.

15. The system of claim 1, further comprising a busbar that can both carry current and dissipate heat.
